(19) United States
(12) Patent Application Publication
(10) Pub. No.: US 2022/0190065 A1
(43) Pub. Date: Jun. 16, 2022

(54) ORGANIC LIGHT-EMITTING DIODE (OLED) DISPLAY PANEL AND MANUFACTURING METHOD THEREOF

(71) Applicant: Shenzhen China Star Optoelectronics Semiconductor Display Technology Co., Ltd., Shenzhen, Guangdong (CN)

(72) Inventors: Yanying DU, Shenzhen, Guangdong (CN); Jinchuan LI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/254,936

(22) PCT Filed: Jul. 14, 2020
(86) PCT No.: PCT/CN2020/101935

§ 371 Date: Dec. 22, 2020

(30) Foreign Application Priority Data
Jun. 5, 2020 (CN) 2020 10505209.9

(51) Int. Cl. H01L 27/32; H01L 51/56

(52) U.S. Cl. CPC H01L 27/3246; H01L 2227/323; H01L 51/56

(57) ABSTRACT

An organic light-emitting diode (OLED) display panel and a manufacturing method thereof are provided. The OLED display panel includes: a substrate and a plurality of pixel units disposed on the substrate, wherein each of the pixel units includes several sub-pixel units, adjacent ones of the sub-pixel units are spaced apart by a pixel definition layer, and a height and a width of the pixel definition layer around each of the sub-pixel units are constant; and wherein each of the sub-pixel units of different colors has a same shape and a same area, such that beneficial effect is provide as improving the uniformity of the display of the display panel and avoiding the occurrence of color shift.

### BACKGROUND OF INVENTION

### Field of Invention

The present application relates to a field of display, in particular to an OLED display panel and a manufacturing method thereof.

### Description of Prior Art

With vigorous development of active-matrix organic light-emitting diode (AMOLED) display technology, AMOLEDs began to be widely used in handheld terminals and large-size displays, and color organic light-emitting diode (OLED) display screens using RGB self-luminous has become the most attractive development and market darling. As for some handheld terminals and large-size display products, display characteristics of wide viewing angle, wide color gamut, and high color accuracy have become the basic requirements. Among them, a large size display has the strongest demand for wide viewing angle, wide color gamut, high color accuracy, and high contrast.

large size display has a wide viewing angle and wide color. Gain high color accuracy and high contrast requirements are most intense.

Due to the inherent demand of organic light-emitting diode (OLED) display devices for improved light-emitting efficiency by resonance-enhanced microcavities, a general OLED device adopts different microcavity optical path designs for RGB three-color pixels to form resonance-enhanced microcavities of corresponding wavelengths. In addition, due to the difference in the luminous efficiency and life span of the three RGB colors, an OLED layout design of unequal RGB display areas is generally employed. Generally, the blue sub-pixels have a larger area than the red and green pixels. In actual production, especially in manufacturing of an OLED device by an evaporation method most widely used at present, in order to ensure accurate linearity and pattern limitation of evaporation material, a layer of pixel definition layer (PDL) is produced on a surface of an anode of a TFT array using polyimide (PI) to ensure that no color mixing occurs, thereby integrating the above-mentioned three layouts and process design to achieve accurate color and wide color gamut when viewing the screen vertically.

In actual use, users generally view the display screen from a direction having a certain angle with a positive direction of the screen, and relative to the influence by occlusion of the pixel definition layer on a light-emitting path of human eye, a ratio of the occlusion effect and a pixel circumference to an area is positively correlated to each other. Since blue has a larger area than other colors, when viewing the screen at an oblique viewing angle, as the viewing angle gradually increases to close to 90°, an observed image gradually becomes bluish green.

Therefore, in the existing OLED display panel technology, there is an urgent need to solve the problem of color shift and impact on display quality of the display panel caused by different areas shielded by the pixel definition layer for the light-emitting function layers of different areas when viewing the display panel at a large viewing angle due to different areas of sub-pixel units of various colors.

### SUMMARY OF INVENTION

The present application relates to a display panel for solving the problems in the prior art that due to the low luminous efficiency of sub-pixel units of various colors, the areas of sub-pixel units of various colors are different, which leads to different areas shielded by the pixel definition layer for the light-emitting function layers of different areas when viewing the display panel at a large viewing angle, thereby causing color shift and impact on the display quality of the display panel.

In order to solve the above problem, technical solutions provided by the present application are as follows:

The present application provides an organic light-emitting diode (OLED) display panel, including: a substrate and a plurality of pixel units disposed on the substrate,

wherein each of the pixel units includes several sub-pixel units, adjacent ones of the sub-pixel units are spaced apart by a pixel definition layer, and a height and a width of the pixel definition layer around each of the sub-pixel units are constant; and

wherein each of the sub-pixel units of different colors has a same shape and a same area.

In an embodiment provided by the present application, each of the pixel units includes a plurality of red sub-pixel units, a plurality of green sub-pixel units, and a plurality of blue sub-pixel units.

In an embodiment provided by the present application, a number of the red sub-pixel unit, a number of the green sub-pixel unit, and a number of the blue sub-pixel unit are different from each other, and the number of the blue sub-pixel unit is greater than the number of red sub-pixel units and greater than the number of green sub-pixel units.

In an embodiment provided by the present application, the height and the width of the pixel definition layer spacing apart the sub-pixel units are constant.

In an embodiment provided by the present application, each of the sub-pixel units has a circular shape or a rectangular shape in a top view, and a rectangular shape or a trapezoidal shape in a cross-sectional view.

In an embodiment provided by the present application, the substrate includes: a first substrate, a buffer layer, a gate, an insulating layer, an active layer, an etching stop layer, a source, a drain, a first through hole, a second through hole, and a planarization layer, and the OLED display panel further includes a first electrode, a light-emitting functional layer, a second electrode, a liner layer, and an OLED encapsulation layer disposed on a side of the substrate.

In an embodiment provided by the present application, the height of the pixel definition layer is greater than a height of the second electrode.

The present application also provides an organic light-emitting diode (OLED) display panel, including: a substrate and a plurality of pixel units disposed on the substrate,

wherein each of the pixel units includes several sub-pixel units, and adjacent ones of the sub-pixel units are spaced apart by a pixel definition layer; and

wherein each of the sub-pixel units of different colors has a same shape and a same area.

In an embodiment provided by the present application, each of the pixel units includes a plurality of red sub-pixel units, a plurality of green sub-pixel units, and a plurality of blue sub-pixel units.

In an embodiment provided by the present application, a number of the red sub-pixel unit, a number of the green sub-pixel unit, and a number of the blue sub-pixel unit are different from each other, and the number of the blue sub-pixel unit is greater than the number of red sub-pixel units and greater than the number of green sub-pixel units.

In an embodiment provided by the present application, the height and the width of the pixel definition layer spacing apart the sub-pixel units are constant.

In an embodiment provided by the present application, each of the sub-pixel units has a circular shape or a rectangular shape in a top view, and a rectangular shape or a trapezoidal shape in a cross-sectional view.

In an embodiment provided by the present application, the substrate includes: a first substrate, a buffer layer, a gate, an insulating layer, an active layer, an etching stop layer, a source, a drain, a first through hole, a second through hole, and a planarization layer, and the OLED display panel further includes a first electrode, a light-emitting functional layer, a second electrode, a liner layer, and an OLED encapsulation layer disposed on a side of the substrate.

In an embodiment provided by the present application, a height of the pixel definition layer is greater than a height of the second electrode.

The present application also provides method of manufacturing the organic light-emitting diode (OLED) display panel, including following steps:

S10, providing the substrate;

S20, sequentially forming a first electrode, a light-emitting functional layer, a second electrode, a capping layer, and a pixel definition layer on the substrate to form the plurality of pixel units; and

S30, dividing each of the pixel units into a plurality of sub-pixel units of a same shape and a same area, wherein a height and a width of the pixel definition layer around each of the sub-pixel units are ensured constant.

In an embodiment provided by the present application, the substrate is made of low-temperature polysilicon or indium gallium zinc oxide.

In an embodiment provided by the present application, the OLED display panel is manufactured by evaporation coating or printing.

Compared with the prior art, beneficial effects of an organic light-emitting diode (OLED) display panel and a manufacturing method thereof provided by the present application are as follows:

1. In an OLED display panel provided by the present application, a plurality of the pixel units are disposed on the substrate, each of the pixel units includes several sub-pixel units, and each of the sub-pixel units has the same shape and a same area, such that areas and angles where the light-emitting functional layers of different colors are shielded by the pixel definition layer are the same when viewing the display panel at a large viewing angle, which improves uniformity of display of the display panel and avoids occurrence of color shift;

2. A method of manufacturing an OLED display panel provided by the present application directly divides each of the pixel units of different colors into a plurality of sub-pixel units of a same shape and a same area, and also guarantees a height and a width of the pixel definition layer disposed between the sub-pixel units are constant.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of an OLED display panel provided by an embodiment of the present application.

FIG. 2 is a schematic structural diagram of pixels of an OLED display panel provided by a first embodiment of the present application.

FIG. 3 is a schematic structural diagram of pixels of an OLED display panel provided by a second embodiment of the present application.

FIG. 4 is a schematic flowchart of a method of manufacturing an OLED display panel provided by an embodiment of the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In the description of this application, it should be understood that the terms “center”, “longitudinal”, “transverse”, “length”, “width”, “thickness”, “upper”, “lower”, “front”, “Rear”, “left”, “right”, “vertical”, “horizontal”, “top”, “bottom”, “inside”, “outside”, “clockwise”, “counterclockwise”, and the like are based on the orientation or positional relationship shown in the drawings, and is merely for the convenience of describing the present invention and simplifying the description, rather than indicating or implying that the device or element referred to must have a specific orientation, structure and operation in a specific orientation, which should not be construed as limitations on the present invention. In addition, the terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless specifically defined otherwise.

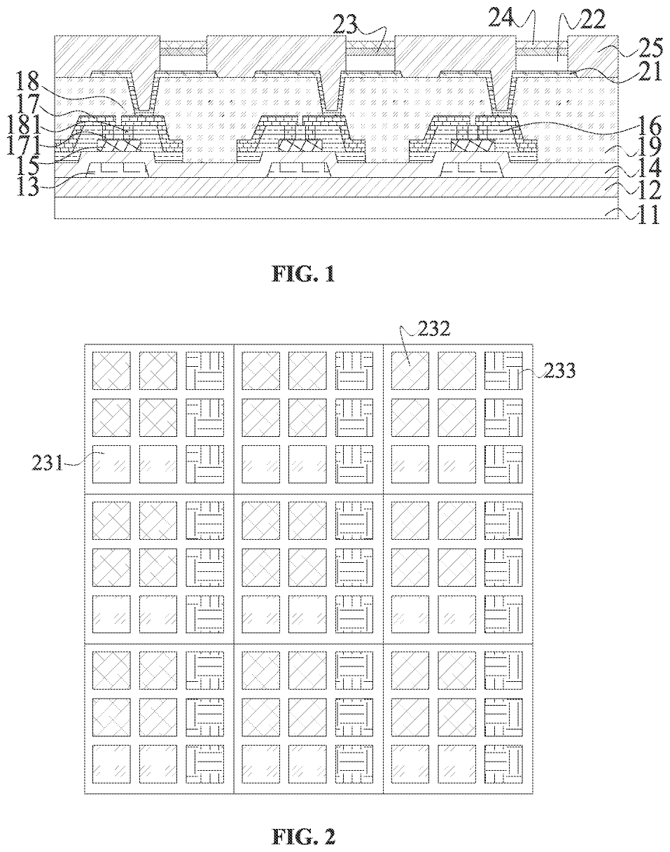

The present application provides an OLED display panel and a method of manufacturing the same, referring to FIGS. 1-4 for details.

When manufacturing an existing OLED display panel, since the luminous efficiency of sub-pixels of different colors is different, the areas of the sub-pixels of different colors are also generally set to be different, resulting in different areas and angles shielded by a pixel definition layer when viewing at a large viewing angle, making the display panel be prone to color shift. Therefore, the present application provides an OLED display panel and a manufacturing method thereof to solve the above problems.

Referring to FIG. 1, it is a schematic structural diagram of an OLED display panel provided by an embodiment of the present application.

The present application provides an OLED display panel. The OLED display panel includes: a substrate 10 and a plurality of pixel units disposed on the substrate 10.

Each of the pixel units includes several sub-pixel units, adjacent ones of the sub-pixel units are spaced apart by a pixel definition layer 25.

Each of the sub-pixel units of different colors has a same shape and a same area. As such, even when viewing at a large viewing angle, an area and an angle of each of the sub-pixel units shielded by the pixel definition layer are the same, and it is not easy to cause a color shift phenomenon.

In some embodiments of the present application, each of the pixel units includes a plurality of the red sub-pixel units 231, a plurality of the green sub-pixel units 232, and a plurality of the blue sub-pixel units 233. In the existing common design of a pixel structure, a number of the sub-pixel unit of each color in each of the pixel units is only one, and then areas of the sub-pixel units are correspondingly designed according to the luminous efficiency of different luminescent materials. According to the present application, each of the pixel units is first divided into a plurality of sub-pixel units, and each of the sub-pixel units has a same shape and a same area, avoiding the problem of color shift caused by shielding of the pixel units by the pixel definition layer when viewing the display panel at a large viewing angle due to different areas of the sub-pixel units.

Further, the numbers of the red sub-pixel units 231, the green sub-pixel units 232 and the blue sub-pixel units 233 are different, and the number of the blue sub-pixel units 233 is larger than that of the red sub-pixel units 231, and greater than the number of the green sub-pixel units 232. Since the luminous efficiency of the sub-pixel units of different colors is different, the areas of the sub-pixel units of different colors are generally set to be different. Therefore, when dividing each of the pixel units into the sub-pixel units of the same area, the lower the luminous efficiency of the sub-pixel unit, the more the number of the sub-pixel units divided. It is well known that the blue sub-pixel unit has the lowest luminous efficiency, therefore, when the sub-pixel units of various colors are divided into equal-sized sub-pixel units, the number of the blue sub-pixel units is the largest, and the number of each of the red and green sub-pixel units is second.

In some embodiments of the present application, the height and the width of the pixel definition layer 25 spacing apart the sub-pixel units are constant. In other words, in order to further ensure that the OLED display panel has no color shift when displaying at a large viewing angle, the height and width of the pixel definition layer disposed around each of the sub-pixel units may be further unified, so that when viewing at a large viewing angle, the area of each of the sub-pixel units shielded by the pixel definition layer is the same.

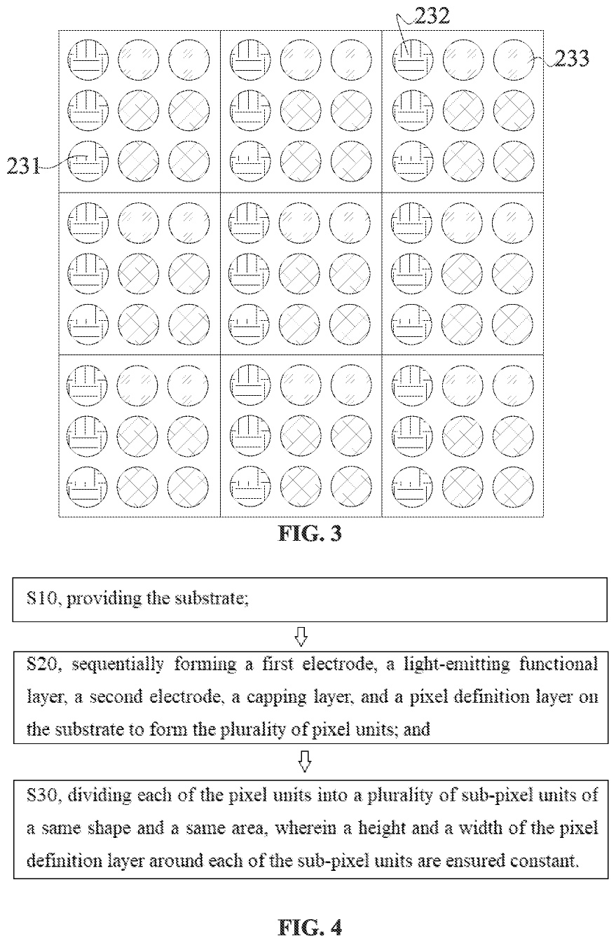

Referring to FIGS. 2 and 3, in some embodiments of the present application, each of the sub-pixel units has a circular shape or a rectangular shape in a top view as shown in FIG. 3. The red sub-pixels 231, the green sub-pixels 232, and the blue sub-pixels 233 are all rectangular. In FIG. 4, the red sub-pixels 231, the green sub-pixels 232, and the blue sub-pixels 233 are all circular. Each of the sub-pixel units has a rectangular shape or a trapezoidal shape in a cross-sectional view.

In some embodiments of the present application, the substrate 10 includes: a first substrate 11, a buffer layer 12, a gate 13, an insulating layer 14, an active layer 15, an etching stop layer 16, a source 17, a drain 18, a first through hole 171, a second through hole 181, and a planarization layer 19. The gate 13, the source 17, and the drain 18 are made of one or more of aluminum (Al), copper (Cu), molybdenum (Mo), and titanium (Ti), the active layer 15 is made of one of amorphous silicon, polycrystalline silicon, and metal oxide, and the buffer layer 12, the insulating layer 14, and the planarization layer 19 are made of an organic material or an inorganic material, such as silicon oxide (SiO2) or silicon nitride (SixNy). The source 17 and the drain 18 are electrically connected to the active layer 15 through the first through hole 171 and the second through hole 181, respectively.

Further, the OLED display panel further includes a first electrode 21, a light-emitting function layer 22, a second electrode 23, a capping layer (CPL) 24, a liner layer, and an OLED encapsulation layer disposed on a side of the substrate 10. The first electrode 21 is an anode, the second electrode 23 is a cathode, the first electrode 21 includes two first conductive layers, and a second conductive layer sandwiched between the two first conductive layers, wherein the first conductive layer is a metal oxide layer, the second conductive layer is a metal layer, and the second electrode 23 is a metal layer. Preferably, a material of the first conductive layer includes indium tin oxide (ITO), a material of the second conductive layer includes silver (Ag), and a material of the second electrode 23 includes one or more of magnesium (Mg) and silver. The liner layer is configured to prevent the mask layer from scratching a film layer in the evaporation process, whose shape is not particularly limited, and is preferably a cylindrical or rectangular. The OLED encapsulation layer is used to isolate external water and oxygen, etc., to prevent the external water and oxygen from eroding internal film layers. The capping layer 24 is made of a material with a large refractive index and a small absorption coefficient, so that the light emission of the top-emitting OLED device can be improved.

Referring to FIG. 4, the present application also provides a method of manufacturing an organic light-emitting diode (OLED) display panel. The OLED display panel uses the above-described OLED display panel. The method includes the following steps:

S10, providing a substrate, wherein the substrate includes: a first substrate, a buffer layer, a gate, an insulating layer, an active layer, an etching stop layer, a source, a drain, a first through hole, a second through hole, and a planarization layer; the OLED display panel further includes a first electrode configured to drive the OLED device layer to emit light; and the first substrate is made of a substrate material including, but not limited to, a glass substrate, a metal substrate, a glass, and/or an organic layer, and/or an organic layer;

S20, sequentially forming a first electrode, a light-emitting functional layer, a second electrode, a capping layer, and a pixel definition layer on the substrate to form the plurality of pixel units, wherein each of the pixel units is evenly divided into a plurality of sub-pixel units same as each other, which is different from the existing design of a pixel structure, so as to reduce the color shift phenomenon of the OLED display panel when displaying at a large viewing angle; and

S30. dividing each of the pixel units into a plurality of sub-pixel units of a same shape and a same area, wherein a height and a width of the pixel definition layer around each of the sub-pixel units are ensured constant. As such, the height and thickness of the pixel definition layer around the sub-pixel units are further defined, thus further reducing the possibility of color shift of the OLED display panel when displaying at a large viewing angle.

In some embodiments of the present application, the substrate is made of low-temperature polysilicon (LTPS) or indium gallium zinc oxide (IGZO). LTPS refers to low-temperature polysilicon, having a conductive channel of P-si, which is the manufacturing process of a new generation of a thin-film transistor liquid crystal display (TFT-LCD). The biggest difference from traditional amorphous silicon displays is that LTPS has a faster response time, high brightness, high resolution, and low power consumption. IGZO refers to IGZO for the conductive channel in TFT. It is an LCD thin film transistor display technology. IGZO technology can increase the resolution of the panel and reduce the cost. However, the IGZO panel is very sensitive to light, water, and oxygen, and its durability can only be used as private consumer goods and cannot be used in a highly reliable military or industrial environment. Compared with amorphous silicon, IGZO can reduce a size of a transistor and increase the aperture ratio of pixels in a liquid crystal panel, which is easier to achieve double the resolution and ten times faster electron mobility, thus becoming the biggest rival of OLED technology.

In some embodiments of the present application, the OLED display panel is manufactured by evaporation or printing.

Therefore, the beneficial effects of an OLED display panel and a manufacturing method thereof provided by the present application are as follows: In the OLED display panel provided by the present application, a plurality of the pixel units are disposed on the substrate, each of the pixel units includes several sub-pixel units, and each of the sub-pixel units has the same shape and a same area, such that areas and angles where the light-emitting functional layers of different colors are shielded by the pixel definition layer are the same when viewing the display panel at a large viewing angle, which improves uniformity of display of the display panel and avoids occurrence of color shift. The method of manufacturing an OLED display panel provided by the present application directly divides each of the pixel units of different colors into a plurality of sub-pixel units of a same shape and a same area, and also guarantees a height and a width of the pixel definition layer disposed between the sub-pixel units are constant.

The OLED display panel and the manufacturing method thereof provided by embodiments of the present application are described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. An organic light-emitting diode (OLED) display panel, comprising: a substrate and a plurality of pixel units disposed on the substrate,
wherein each of the pixel units comprises several sub-pixel units, adjacent ones of the sub-pixel units are spaced apart by a pixel definition layer, and a height and a width of the pixel definition layer around each of the sub-pixel units are constant; and
wherein each of the sub-pixel units of different colors has a same shape and a same area.

2. The OLED display panel according to claim 1, wherein each of the pixel units comprises a plurality of red sub-pixel units, a plurality of green sub-pixel units, and a plurality of blue sub-pixel units.

3. The OLED display panel according to claim 2, wherein a number of the red sub-pixel unit, a number of the green sub-pixel unit, and a number of the blue sub-pixel unit are different from each other, and the number of the blue sub-pixel unit is greater than the number of red sub-pixel units and greater than the number of green sub-pixel units.

4. The OLED display panel according to claim 2, wherein the height and the width of the pixel definition layer spacing apart the sub-pixel units are constant.

5. The OLED display panel according to claim 1, wherein each of the sub-pixel units has a circular shape or a rectangular shape in a top view, and a rectangular shape or a trapezoidal shape in a cross-sectional view.

6. The OLED display panel according to claim 1, wherein the substrate comprises: a first substrate, a buffer layer, a gate, an insulating layer, an active layer, an etching stop layer, a source, a drain, a first through hole, a second through hole, and a planarization layer, and the OLED display panel further comprises a first electrode, a light-emitting functional layer, a second electrode, a liner layer, and an OLED encapsulation layer disposed on a side of the substrate.

7. The OLED display panel according to claim 6, wherein the height of the pixel definition layer is greater than a height of the second electrode.

8. An organic light-emitting diode (OLED) display panel, comprising: a substrate and a plurality of pixel units disposed on the substrate,
wherein each of the pixel units comprises several sub-pixel units, and adjacent ones of the sub-pixel units are spaced apart by a pixel definition layer; and
wherein each of the sub-pixel units of different colors has a same shape and a same area.

9. The OLED display panel according to claim 8, wherein each of the pixel units comprises a plurality of red sub-pixel units, a plurality of green sub-pixel units, and a plurality of blue sub-pixel units.

10. The OLED display panel according to claim 9, wherein a number of the red sub-pixel unit, a number of the green sub-pixel unit, and a number of the blue sub-pixel unit are different from each other, and the number of the blue sub-pixel unit is greater than the number of red sub-pixel units and greater than the number of green sub-pixel units.

11. The OLED display panel according to claim 9, wherein the height and the width of the pixel definition layer spacing apart the sub-pixel units are constant.

12. The OLED display panel according to claim 8, wherein each of the sub-pixel units has a circular shape or a rectangular shape in a top view, and a rectangular shape or a trapezoidal shape in a cross-sectional view.

13. The OLED display panel according to claim 8, wherein the substrate comprises: a first substrate, a buffer layer, a gate, an insulating layer, an active layer, an etching stop layer, a source, a drain, a first through hole, a second through hole, and a planarization layer, and the OLED display panel further comprises a first electrode, a light-emitting functional layer, a second electrode, a liner layer, and an OLED encapsulation layer disposed on a side of the substrate.

14. The OLED display panel according to claim 13, wherein a height of the pixel definition layer is greater than a height of the second electrode.

15. A method of manufacturing the organic light-emitting diode (OLED) display panel of claim 1, the method comprising following steps:
S10, providing the substrate;
S20, sequentially forming a first electrode, a light-emitting functional layer, a second electrode, a capping layer, and a pixel definition layer on the substrate to form the plurality of pixel units; and
S30, dividing each of the pixel units into a plurality of sub-pixel units of a same shape and a same area, wherein a height and a width of the pixel definition layer around each of the sub-pixel units are constant.

16. The method of manufacturing the OLED display panel according to claim 15, wherein the substrate is made of low-temperature polysilicon or indium gallium zinc oxide.

17. The method of manufacturing the OLED display panel according to claim 15, wherein the OLED display panel is manufactured by evaporation coating or printing.
